(19) United States
(12) Patent Application Publication
(10) Pub. No.: US 2010/0102454 A1
(43) Pub. Date: Apr. 29, 2010

(54) SEMICONDUCTOR DEVICE AND METHOD OF MANUFACTURING THE SEMICONDUCTOR DEVICE

(75) Inventor: Kazutaka AKIYAMA, Chiba (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: KABUSHIKI KAISHA TOSHIBA, Tokyo (JP)

(21) Appl. No.: 12/497,869

(22) Filed: Jul. 6, 2009

(30) Foreign Application Priority Data
Oct. 27, 2008 (JP) 2008-275865

(51) Int. Cl. H01L 23/48; H01L 21/28

(52) U.S. Cl. 257/774; 438/612; 257/E23.011; 257/E21.158

(57) ABSTRACT

When an etch stopper film is stacked on a pad electrode in which an opening is provided and a through electrode is embedded in a through hole formed in a semiconductor substrate, a distal end of the through electrode penetrates a part of the pad electrode via the opening and is stopped by the etch stopper film.

### CROSS-REFERENCE TO RELATED APPLICATIONS

This application is based upon and claims the benefit of priority from the prior Japanese Patent Application No. 2008-275865, filed on Oct. 27, 2008; the entire contents of which are incorporated herein by reference.

### BACKGROUND OF THE INVENTION

1. Field of the Invention

The present invention relates to a semiconductor device and a method of manufacturing the semiconductor device, and, more particularly to a method of forming a through electrode for leading out an electrode from the rear surface of a semiconductor substrate.

2. Description of the Related Art

According to requests for a reduction in size and an increase in functions of electronic apparatuses such as cellular phones, there is a demand for improvement of packaging density of a semiconductor device that is a main component of the electronic apparatuses. As a method of improving the packaging density of the semiconductor device, there is a method of stacking semiconductor chips. As a method of stacking semiconductor chips, a method of forming a through electrode for leading out an electrode from the rear surface of a semiconductor substrate is considered prospective because the semiconductor chips can be flip-chip mounted without the number of stacks being limited.

When the through electrode for leading out the electrode from the rear surface of the semiconductor substrate is formed, a pad electrode for connecting the through electrode is formed in a multilayer wiring layer on the semiconductor substrate separately from a pad electrode for external connection provided on the semiconductor substrate. A through hole is formed from the rear surface of the semiconductor substrate and the through electrode is embedded in the through hole to connect the through electrode to the pad electrode provided on the semiconductor substrate.

For example, Japanese Patent Application Laid-Open No. 2004-146597 discloses a method of, to improve adhesion of wires in a pad section, providing Cu damascene wiring and a pad section therefor from the upper surface to the inside of a SiO₂ film on a Si substrate and providing a contact plug to reach the inside of the pad section of the Cu damascene wiring from the lower surface of Al dual damascene wiring formed on the Cu damascene wiring.

However, in the method disclosed in Japanese Patent Application Laid-Open No. 2004-146597, to form the contact plug reaching the inside of the pad section of the Cu damascene wiring, it is necessary to form an opening in the SiO₂ film in which the pad section of the Cu damascene wiring is provided from the upper surface to the inside thereof. Therefore, it is likely that the opening penetrates through the SiO₂ film and the contact plug embedded in the opening reaches a lower wiring layer below the Cu damascene wiring. As a result, the Cu damascene wiring or the Al dual damascene wiring and a lower layer wiring layer below the wirings are short-circuited and cause a short-circuit failure.

### BRIEF SUMMARY OF THE INVENTION

A semiconductor device according to an embodiment of the present invention comprises: a semiconductor substrate on which a semiconductor element is formed on a front side; a wiring layer formed on the semiconductor substrate; a first pad electrode formed in the wiring layer; an etch stopper film of an insulator that is formed on the first pad electrode and insulates the wiring layer; and a through electrode that pierces through the semiconductor substrate from a rear surface of the semiconductor substrate, penetrates a part of the first pad electrode, and is stopped by the etch stopper film.

A semiconductor device according to an embodiment of the present invention comprises: a semiconductor substrate on which a semiconductor element is formed on a front side; a wiring layer formed on the semiconductor substrate; a first pad electrode formed in the wiring layer; a stopper electrode formed in a layer above the first pad electrode to overlap the first pad electrode; and a through electrode that pierces through the semiconductor substrate from a rear surface of the semiconductor substrate, penetrates a part of the first pad electrode, and is stopped by the stopper electrode.

A method of manufacturing a semiconductor device according to an embodiment of the present invention comprises: forming, on a semiconductor substrate, a wiring layer in which a pad electrode having a first opening is provided; forming, on the pad electrode, an etch stopper film of an insulator that insulates the wiring layer; forming a through hole that pierces through the semiconductor substrate from a rear surface of the semiconductor substrate; forming, in the insulator, a second opening that reaches the etch stopper film via the first opening and the through hole; and forming a through electrode embedded in the first and second openings and the through hole, electrically connected to the pad electrode, and drawn out to a rear side of the semiconductor substrate.

### BRIEF DESCRIPTION OF THE DRAWINGS

FIG. 1A is a sectional view of a schematic configuration of a semiconductor device according to a first embodiment of the present invention;

FIG. 1B is a plan view of an example of a schematic configuration of a pad electrode 21b shown in FIG. 1A;

FIG. 1C is a plan view of another example of the schematic configuration of the pad electrode 21b shown in FIG. 1A;

FIG. 2 is a sectional view for explaining a method of manufacturing a semiconductor device according to a second embodiment of the present invention;

FIG. 3 is a sectional view for explaining the method of manufacturing a semiconductor device according to the second embodiment;

FIG. 4 is a sectional view for explaining the method of manufacturing a semiconductor device according to the second embodiment;

FIG. 5 is a sectional view for explaining the method of manufacturing a semiconductor device according to the second embodiment;

FIG. 6 is a sectional view for explaining the method of manufacturing a semiconductor device according to the second embodiment;

FIG. 7 is a sectional view of a schematic configuration of a semiconductor module according to a third embodiment of the present invention;

FIG. 8 is a sectional view of a schematic configuration of a semiconductor module according to a fourth embodiment of the present invention;

FIG. 9 is a sectional view of a schematic configuration of a semiconductor device according to a fifth embodiment of the present invention; and

FIG. 10 is a sectional view of a schematic configuration of a semiconductor device according to a sixth embodiment of the present invention.

### DETAILED DESCRIPTION OF THE INVENTION

Exemplary embodiments of the present invention are explained in detail below with reference to the accompanying drawings. The present invention is not limited by the embodiments.

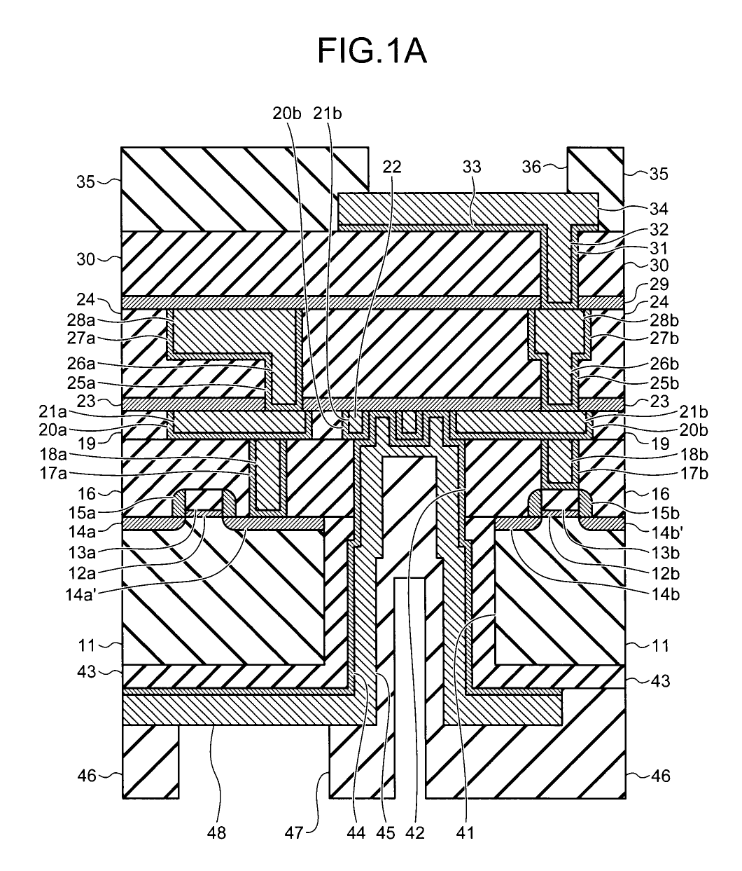

FIG. 1A is a sectional view of a schematic configuration of a semiconductor device according to a first embodiment of the present invention. FIG. 1B is a plan view of an example of a schematic configuration of a pad electrode 21b shown in FIG. 1A. FIG. 1C is a plan view of another example of the schematic configuration of the pad electrode 21b shown in FIG. 1A.

In FIG. 1A, impurity introduced layers 14a, 14a′, 14b, and 14b′ separated from one another are formed in a semiconductor substrate 11. A material of the semiconductor substrate 11 is not limited to Si and can be selected out of, for example, Ge, SiGe, SiC, SiSn, PbS, GaAs, InP, GaP, GaN, ZnSe, and GaInAsP. The thickness of the semiconductor substrate 11 can be set to, for example, about 70 micrometers.

A gate electrode 13a is formed via a gate insulating film 12a on the semiconductor substrate 11 between the impurity introduced-layer 14a and 14a′. A sidewall 15a is formed on a side of the gate electrode 13a. A gate electrode 13b is formed on the semiconductor substrate 11 between the impurity introduced layers 14b and 14b′ via the gate insulating film 12b. A sidewall 15b is formed on a side of the gate electrode 13b.

An interlayer insulating film 16 is formed on the semiconductor substrate 11 and the gate electrodes 13a and 13b. Contact plugs 18a and 18b are embedded in the interlayer insulating film 16 via barrier metal films 17a and 17b, respectively. The contact plug 18a is connected to the impurity introduced layer 14a′. The contact plug 18b is connected to the gate electrode 13b.

An interlayer insulating film 19 is formed on the interlayer insulating film 16 and the contact plugs 18a and 18b. Wiring 21a is embedded in the interlayer insulating film 19 via a barrier metal film 20a. A pad electrode 21b is embedded in the interlayer insulating film 19 via a barrier metal layer 20b.

The wiring 21a is connected to the contact plug 18a. The pad electrode 21b is connected to the contact plug 18b. Openings 22 for causing a through electrode 45 to penetrate are formed in the pad electrode 21b. As shown in FIG. 1B, the openings 22 can be formed by providing a hole in the pad electrode 21b. Alternatively, as shown in FIG. 1C, a pad electrode 21b′ in which slit-like openings 22′ are formed can be used instead of the pad electrode 21b. An area of the pad electrode 21b can be set to be larger than an area of a distal end of the through electrode 45. An aperture ratio of the pad electrode 21b is preferably set within a range of 10% to 80%. For example, the size of the pad electrode 21b can be set to 80 μm square. The openings 22 having the size of 5 μm square can be arranged in the pad electrode 21b at 15 μm intervals. The thickness of the pad electrode 21b can be set to, for example, about 0.2 micrometers.

An etch stopper film 23 is formed on the interlayer insulating film 19, the wiring 21a, and the pad electrode 21b. The thickness of the etch stopper film 23 can be set to, for example, about 0.1 micrometer. An interlayer insulating film 24 is formed on the etch stopper film 23. Contact plugs 26a and 26b are embedded in the etch stopper film 23 and the interlayer insulating film 24 via barrier metal films 25a and 25b, respectively. Wirings 28a and 28b are embedded in the etch stopper film 23 and the interlayer insulating film 24 via barrier metal films 27a and 27b, respectively. The wiring 28a is connected to the wiring 21a via the contact plug 26a. The wiring 28b is connected to the wiring 21b via the contact plug 26b.

An etch stopper film 29 is formed on the interlayer insulating film 24 and the wirings 28a and 28b. An interlayer insulating film 30 is formed on the etch stopper film 29. A contact plug 32 is embedded in the etch stopper film 29 and the interlayer insulating film 30 via a barrier metal film 31.

A pad electrode 34 is formed on the interlayer insulating film 30 via a barrier metal film 33. The pad electrode 34 is connected to the wiring 28b via the contact plug 32. A protective film 35 is formed on the interlayer insulating film 30 and the pad electrode 34. An opening 36 for exposing the surface of the pad electrode 34 is formed in the protective film 35.

The etch stopper films 23 and 29 can be formed of a material having an etching rate smaller than that of the interlayer insulating films 16, 19, 24, and 30. For example, a SiO₂ film or a Low-k film can be used as the interlayer insulating films 16, 19, 24, and 30. For example, a film containing SiN, SiCN, or SiC as a main component can be used as the etch stopper films 23 and 29. For example, a SiN film can be used as the protective film 35. A material containing Cu, Al, W, or Sn as a main component can be used as a material of the contact plugs 18a, 18b, 26a, 26b, and 32, the wirings 21a, 28a, and 28b, and the pad electrodes 21b and 34. Ta, TaN, Ti, or TiN or a stacked structure of these components can be used as a material of the barrier metal films 17a, 17b, 20a, 20b, 25a, 25b, 27a, 27b, 31, and 33.

A through hole 41 that pierces through the semiconductor substrate 11 from the rear surface is formed in the semiconductor substrate 11. As a ratio of the depth and the diameter (an aspect ratio) of the through hole 41, the depth is preferably set to be equal to or smaller than 5 with respect to the diameter 1. The depth is more preferably set to be equal to or smaller than 2 with respect to the diameter 1. For example, when the depth of the through hole 41 is 70 micrometers, the diameter of the through hole 41 can be set to 70 micrometers.

An insulating layer 43 is formed on the rear surface of the semiconductor substrate 11 and the sidewall of the through hole 41. An opening 42 for exposing the barrier metal film 20b below the pad electrode 21b is formed in the interlayer insulating film 16 and the insulating layer 43 via the through hole 41.

The through electrode 45 electrically connected to the pad electrode 21b and drawn out to the rear side of the semiconductor substrate 11 is embedded in the through hole 41 and the opening 42 via a barrier metal film 44. The distal end of the through electrode 45 penetrates a part of the pad electrode 21b via the openings 22 and is stopped by the etch stopper film 23.

A pad electrode 48 connected to the through electrode 45 is formed on the rear surface of the semiconductor substrate 11. A solder resist film 46 is formed on the rear side of the semiconductor substrate 11 to cover the through electrode 45 and the pad electrode 48 while entering the through hole 41. An opening 47 for exposing the pad electrode 48 is formed in the solder resist film 46.

For example, a SiO₂ film can be used as the insulating layer 43. Ti or Tin or a stacked structure of these components can be used as a material of the barrier metal film 44. A material containing Cu, Al, W, or Sn as a main component can be used as a material of the through electrode 45 and the pad electrode 48.

When the depth of the through hole 41 is 70 micrometers and the diameter thereof is 70 micrometers, the thickness of the insulating layer 43 can be set to, for example, 1 micrometer. The thickness of the through hole 45 can be set to, for example, 10 micrometers. The thickness of the solder resist film 46 on the bottom surface of the through hole 41 can be set to, for example, 40 micrometers. The thickness of the solder resist film 46 on the sidewall of the through hole 41 can be set to, for example, 20 micrometers.

It is possible to increase a contact area between the through electrode 45 and the pad electrode 21b by forming the distal end of the through electrode 45 to penetrate a part of the pad electrode 21b via the openings 22. Therefore, it is possible to improve adhesion between the through electrode 45 and the pad electrode 21b. Even when the barrier metal films 20b and 42 are interposed between the through electrode 45 and the pad electrode 21b, the through electrode 45 and the pad electrode 21b can be less easily peeled off. When the distal end of the through electrode 45 is formed to penetrate a part of the pad electrode 21b via the openings 22 with the barrier metal film 20b left, for example, even when the reactive ion etching (RIE) method or the wet method is used, the openings 22 are not formed in direct contact with the electrode material of the pad electrode 21b. Therefore, corrosion and the like of the electrode material can be prevented.

Because the openings 22 are provided in the pad electrode 21b, even when a soft material such as Cu is used for the pad electrode 21b, erosion caused by excessive removal of the pad electrode 21b can be suppressed during CMP for embedding the pad electrode 21b in the interlayer insulating film 19 with the damascene method. Therefore, the resistance of the pad electrode 21b can be prevented from increasing and reliability thereof is prevented from deteriorating because of electromigration, stress migration, and the like.

Because the etch stopper film 23 is stacked on the pad electrode 21b, even when the openings 22 are provided in the pad electrode 21b, the opening 42 can be prevented from penetrating the interlayer insulating film 24 via the openings 22 to reach upper layer wiring formed in a layer above the pad electrode 21b during etching for forming the opening 42 in the interlayer insulating film 16. Therefore, even when the openings 22 are provided in the pad electrode 21b, the through electrode 45 can be prevented from being connected to the upper layer wiring formed in the layer above the pad electrode 21b. A short-circuit failure of the through electrode 45 can be prevented.

For example, when the distal end of the through electrode 45 is formed to penetrate the openings 22 using the RIE method, for example, the semiconductor substrate 11 is formed of Si and the interlayer insulating films 16 and 19 are formed of SiO₂. Then, a processing selection ratio between the semiconductor substrate 11 and the interlayer insulating films 16 and 19 is about 100 when the semiconductor substrate 11 is processed by using a SF₆ gas. Therefore, even if the semiconductor substrate 11 having the thickness of 70 micrometers is processed, the processing is stopped at a boundary between the semiconductor substrate 11 and the interlayer insulating film 16. A processing selection ratio between the interlayer insulating film 19 and the barrier metal film 20b is equal to or larger than 30 when the interlayer insulating film 16 and the interlayer insulating film 19 including the openings 22 are processed by using, for example, a C₄F₈ gas. Therefore, the openings 22 can be processed by using the barrier metal film 20b as a mask.

Because the etch stopper film 23 is stacked on the pad electrode 21b, the etch stopper film 23 can surround the pad electrode 21b in cooperation with the barrier metal film 20b. Therefore, it is possible to prevent the material of the pad electrode 21b from diffusing with the etch stopper film 23 and the barrier metal film 20b. Even when a material such as Cu is used for the pad electrode 21b, it is possible to prevent Cu or the like from intruding into the semiconductor substrate 11 and the gate electrodes 13a and 13b. It is possible to prevent characteristics of a field effect transistor formed in the semiconductor substrate 11 from being deteriorated and prevent reliability of the gate electrodes 13a and 13b from being deteriorated.

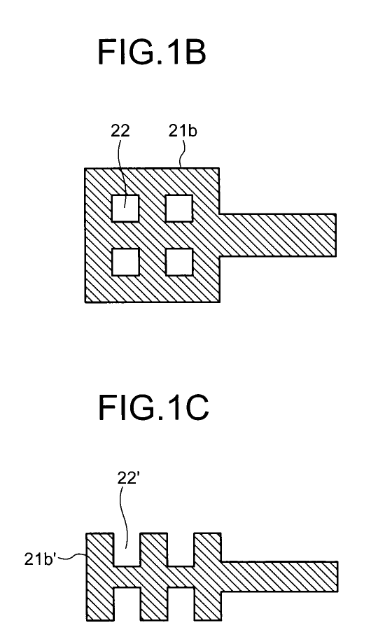

FIGS. 2 to 6 are sectional views of a method of manufacturing a semiconductor device according to a second embodiment of the present invention.

In FIG. 2, the gate electrodes 13a and 13b are formed on the semiconductor substrate 11 via the gate insulating films 12a and 12b, respectively. After the sidewalls 15a and 15b are formed on the sides of the gate electrodes 13a and 13b, respectively, impurities are ion-injected into the semiconductor substrate 11 to form the impurity introduced layers 14a, 14a′, 14b, and 14b′.

The interlayer insulating film 16 is formed on the semiconductor substrate 11 and the gate electrodes 13a and 13b by using a method such as the CVD method. For example, a SiO₂ film can be used as a material of the interlayer insulating film 16. The thickness of the interlayer insulating film 16 can be set to, for example, 0.5 micrometer.

Subsequently, the contact plug 18a connected to the impurity introduced layer 14a′ via the barrier metal film 17a is embedded in the interlayer insulating film 16 by using a method such as the damascene method. The contact plug 18b connected to the gate electrode 13b via the barrier metal film 17b is embedded in the interlayer insulating film 16 by using the method.

The interlayer insulating film 19 is formed on the interlayer insulating film 16 and the contact plugs 18a and 18b by using the method such as the CVD method.

The wiring 21a connected to the contact plug 18a via the barrier metal film 20a is embedded in the interlayer insulating film 19 by using the method such as the damascene method. The pad electrode 21b connected to the contact plug 18b via the barrier metal film 20b is embedded in the interlayer insulating film 19 by using the method.

Because the openings 22 are provided in the pad electrode 21b, even when a soft material such as Cu is used for the pad electrode 21b, erosion caused by excessive removal of the pad electrode 21b can be suppressed during CMP for embedding the pad electrode 21b in the interlayer insulating film 19 with the damascene method.

The wiring 21a and the pad electrode 21b can be formed by using, besides the damascene method, a method of patterning a conductive film using the photolithography method and the dry etching technology.

The etch stopper film 23 is formed on the interlayer insulating film 19, the wiring 21a, and the pad electrode 21b by using the method such as the CVD method. For example, a SiN film can be used as a material of the etch stopper film 23. The thickness of the etch stopper film 23 can be set to, for example, 0.1 micrometer.

The etch stopper film 23 can also have a function of a barrier film. The etch stopper film 23 can prevent the material of the pad electrode 21b from diffusing in cooperation with the barrier metal film 20b. Therefore, even when a material such as Cu is used for the pad electrode 21b, it is possible to prevent Cu or the like from intruding into the semiconductor substrate 11 and the gate electrodes 13a and 13b. It is possible to prevent deterioration in characteristics of a field effect transistor and the like.

The interlayer insulating film 24 is formed on the etch stopper film 23 by using the method such as the CVD method. The contact plug 26a and the wiring 28a connected to the wiring 21a are embedded in the etch stopper film 23 and the interlayer insulating film 24 via the barrier metal films 25a and 27a, respectively, by using a method such as the dual damascene method. The contact plug 26b and the wiring 28b connected to the pad electrode 21b are embedded in the etch stopper film 23 and the interlayer insulating film 24 via the barrier metal films 25b and 27b, respectively, by using the method.

The etch stopper film 29 is formed on the interlayer insulating film 19 and the wirings 28a and 28b by using the method such as the CVD method. The interlayer insulating film 30 is formed on the etch stopper film 29 by using the method such as the CVD method. The contact plug 32 connected to the wiring 28b via the barrier metal film 31 is embedded in the etch stopper film 29 and the interlayer insulating film 30 by using the method such as the damascene method.

The pad electrode 34 connected to the contact plug 32 is formed on the interlayer insulating film 30 via the barrier metal film 33. The protective film 35 is formed on the interlayer insulating film 30 and the pad electrode 34. The opening 36 for exposing the surface of the pad electrode 34 is formed in the protective film 35.

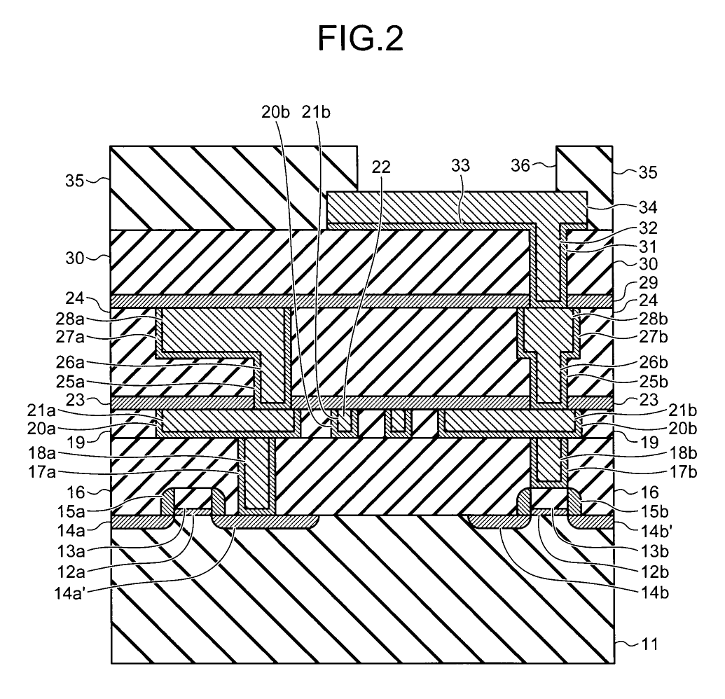

As shown in FIG. 3, the thickness of the semiconductor substrate 11 is reduced to be equal to or smaller than about 100 micrometers by grinding the rear surface of the semiconductor substrate 11. When the thickness of the semiconductor substrate 11 is reduced to be equal to or smaller than about 100 micrometers, it is preferable to bond a support substrate on the front surface of the semiconductor substrate 11. The support substrate can be preferably peeled off when necessary after being bonded to the semiconductor substrate 11.

A resist pattern including an opening corresponding to the width of the through hole 41 is formed on the rear surface of the semiconductor substrate 11 by using the photolithography technology. Dry etching of the semiconductor substrate 11 is performed by using the resist pattern as a mask to form the through hole 41 in the semiconductor substrate 11. The resist pattern formed on the rear surface of the semiconductor substrate 11 is removed by using a method such as the ashing method.

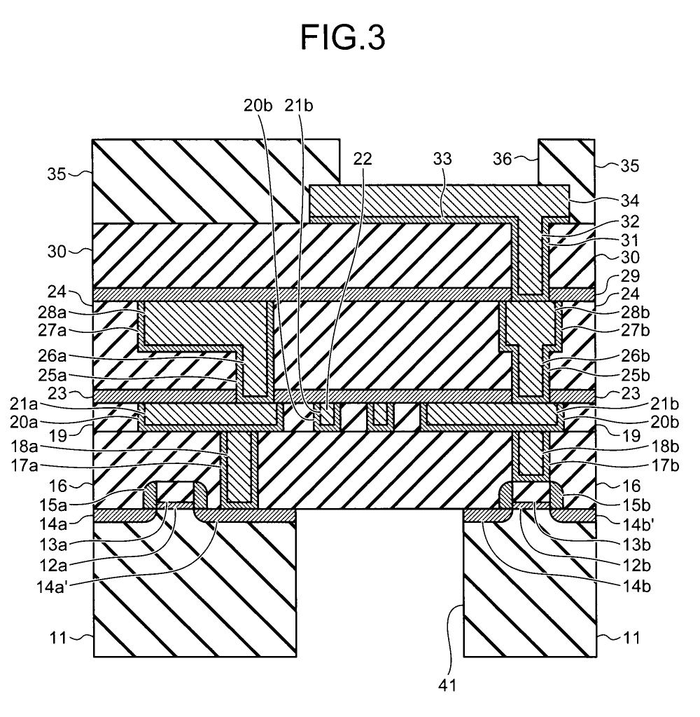

As shown in FIG. 4, the insulating layer 43 is formed on the rear surface of the semiconductor substrate 11 to cover the sidewall of the through hole 41 by using the method such as the CVD method. For example, a SiO₂ film can be used as the insulating layer 43. The thickness of the insulating layer 43 can be set to, for example, 1 micrometer.

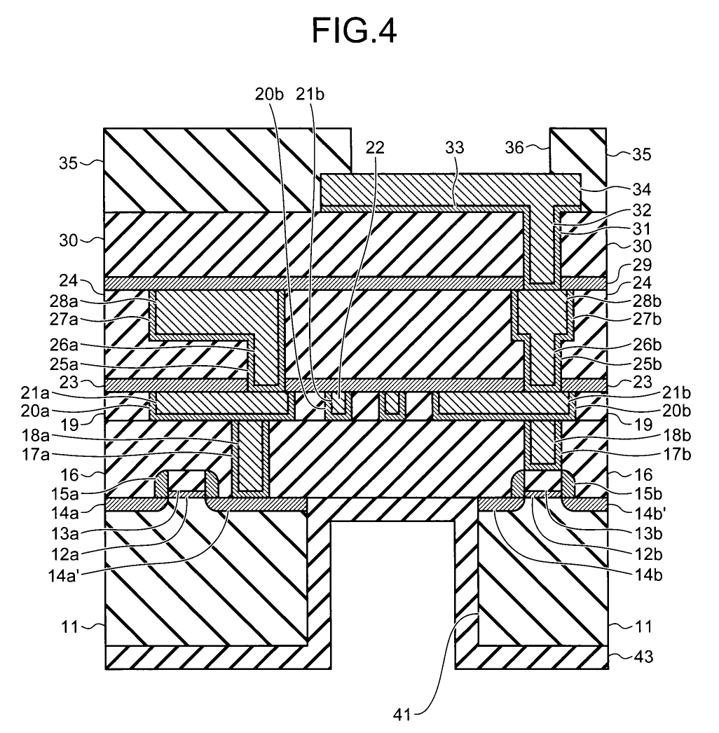

As shown in FIG. 5, dry etching of the insulating layer 43 and the interlayer insulating films 16 and 19 is performed to form the opening 42 in the insulating layer 43 and the interlayer insulating film 16 and remove the interlayer insulating film 19 in the openings 22 of the pad electrode 21b.

Because the etch stopper film 23 is stacked on the pad electrode 21b, when the interlayer insulating film 19 in the openings 22 is removed, it is possible to prevent the opening 42 from penetrating the interlayer insulating film 24 via the openings 22 and reaching the upper layer wiring formed in the layer above the pad electrode 21b.

When SiO₂ is used as a material of the insulating layer 43 and the interlayer insulating films 16 and 19 and SiN is used as a material of the etch stopper film 23, a selection ratio equal to or larger than 20 can be secured by using a C₄F₈/CO/Ar etching gas between the insulating layer 43 and the interlayer insulating films 16 and 19 and the etch stopper film 23.

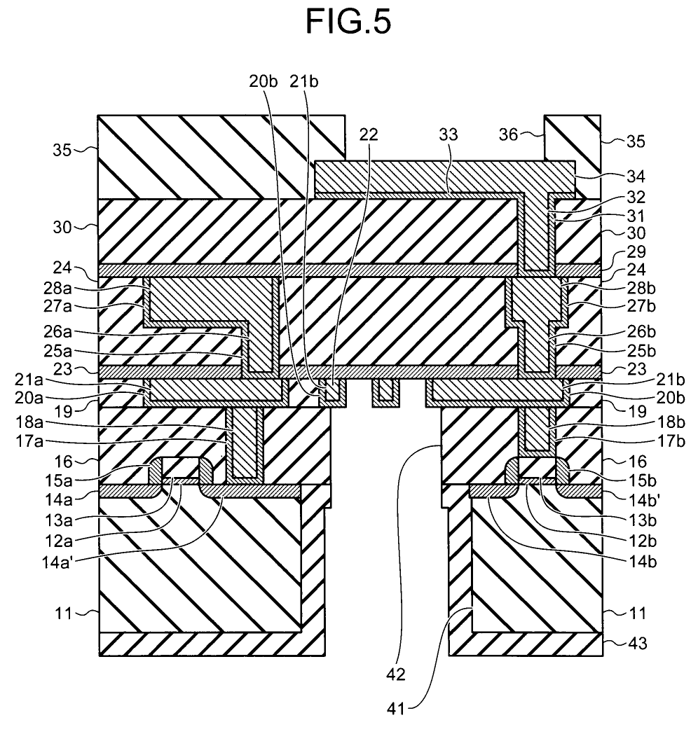

As shown in FIG. 6, the barrier metal film 44 is formed on the rear surface of the semiconductor substrate 11 to cover the rear surface of the pad electrode 21b and the sidewalls of the openings 22 and 42 and the through hole 41 by using a method such as the sputtering method. The barrier metal film 44 can also have a function of a seed electrode.

A resist pattern for selective plating is formed on the barrier metal film 44 by using the photolithography technology. The through electrode 45 electrically connected to the pad electrode 21b and the pad electrode 48 connected to the through electrode 45 are formed on the barrier metal film 44 by performing electrolytic plating using the resist pattern for selective plating as a mask.

After the resist pattern for selective plating is removed, the barrier metal film 44 exposed from the through electrode 45 and the pad electrode 48 is removed by wet-etching the barrier metal film 44 with an acid etching liquid using the through electrode 45 and the pad electrode 48 as masks.

Because the openings 22 are provided in the pad electrode 21b, the distal end of the through electrode 45 can be formed to penetrate a part of the pad electrode 21b. It is possible to improve adhesion between the through electrode 45 and the pad electrode 21b.

As shown in FIG. 1A, the solder resist film 46 that covers the through electrode 45 and the pad electrode 48 is formed on the rear side of the semiconductor substrate 11 to be embedded in the through hole 41. The opening 47 for exposing the surface of the pad electrode 48 is formed in the solder resist film 46.

For example, an acrylic organic material can be used as a material of the solder resist film 46. The solder resist film 46 can function as an anticorrosive for preventing the through electrode 45 and the pad electrode 48 from being corroded by moisture or the like.

When the adhesion between the through electrode 45 and the pad electrode 21b is improved, it is possible to prevent the through electrode 45 from peeling off from the pad electrode 21b even when thermal contraction is caused by a crosslinking reaction of the solder resist film 46 or the through electrode 45 has hysteresis stress, i.e., the through electrode 45 repeats expansion and contraction with respect to temperature.

According to the manufacturing method explained above, a via chain structure in which one hundred through electrodes 45 were lined up was formed. A temperature cycle test at temperature from −55° C. to 150° C. was carried out by using fifty test chips in which this via chain structure was formed. As a result, a failure did not occur in any of the test chips in the test for 1000 cycles. When a PCT test at temperature of 130° C. and humidity of 85% was performed for 1000 hours by using the same test chips, a failure did not occur either.

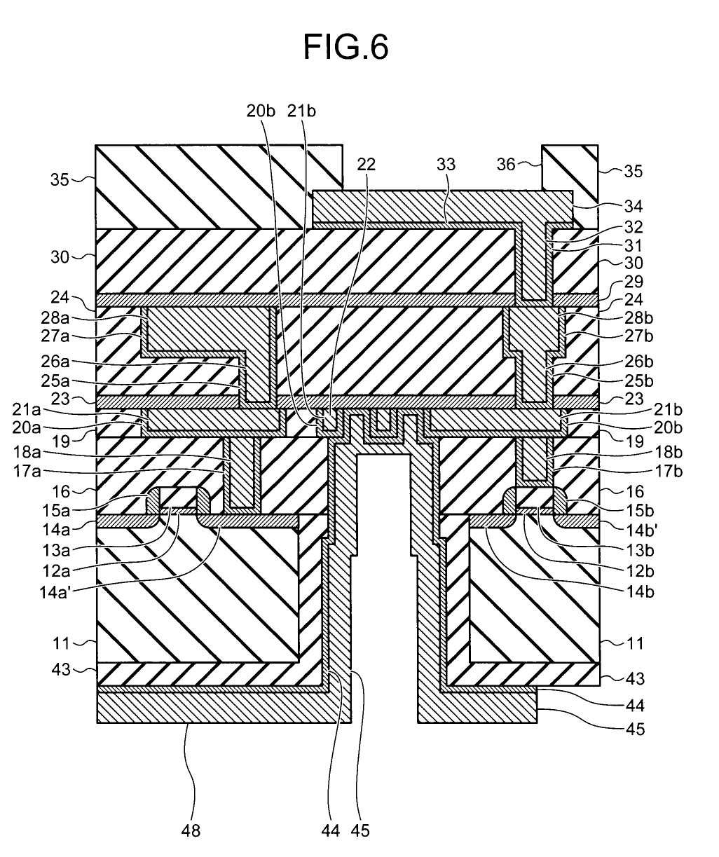

FIG. 7 is a sectional view of a schematic structure of a semiconductor module according to a third embodiment of the present invention.

In FIG. 7, a multilayer wiring layer 52 is formed on a semiconductor substrate 51 on which a semiconductor element such as a transistor is formed on the front side. A pad electrode 53 is formed in a layer under the multilayer wiring layer 52. A pad electrode 55 is formed in a top layer of the multilayer wiring layer 52. The pad electrodes 53 and 55 are connected to each other via a contact plug 54. The multilayer wiring layer 52 can be configured the same as the wiring layer formed on the semiconductor substrate 11 shown in FIG. 1A. In particular, the pad electrode 53 can be configured the same as the pad electrode 21b shown in FIG. 1A. For example, an imaging element used for a CCD image sensor, a CMOS image sensor, and the like can be formed on the semiconductor substrate 51 on which the multilayer wiring layer 52 is formed.

A through hole 61 piercing through the semiconductor substrate 51 from the rear surface is formed in the semiconductor substrate 51. An insulating layer 62 is formed on the rear surface of the semiconductor substrate 51 and the sidewall of the through hole 61. The pad electrode 53 is electrically connected to the through hole 61. A through electrode 63 drawn out to the rear side of the semiconductor substrate 51 is embedded in the through hole 61 via the insulating layer 62. A pad electrode 67 connected to the through electrode 63 is formed on the rear surface of the semiconductor substrate 51 via the insulating layer 62.

A solder resist film 64 that covers the through electrode 63 and the pad electrode 67 is formed on the insulating layer 62 to be embedded in the through hole 61. An opening 65 for exposing the surface of the pad electrode 67 is formed in the solder resist film 64. A protruding electrode 66 is formed on the pad electrode 67. For example, a solder ball or an Au bump, a Cu bump or an Ni bump covered with a solder material, or the like can be used as the protruding electrode 66. The structure of the through electrode 63 formed on the semiconductor substrate 51 can be the same as the structure of the through electrode 45 shown in FIG. 1A.

A glass substrate 71 is bonded on the multilayer wiring layer 52 on the semiconductor substrate 51 via a bonding layer 72. For example, a photoresist can be used as the bonding layer 72.

A land electrode 77 is formed on a mother board 76. The semiconductor substrate 51 is flip-chip mounted on the mother board 76 by joining the protruding electrode 66 to the land electrode 77. The semiconductor substrate 51 to which the glass substrate 71 is bonded is arranged in a lens barrel 75. A lens 74 is installed on the glass substrate 71 via a filter plate 73.

Because the through electrode 63 is formed on the semiconductor substrate 51, it is unnecessary to electrically connect the semiconductor substrate 51 and the mother board 76 with a bonding wire and reduce a packaging area.

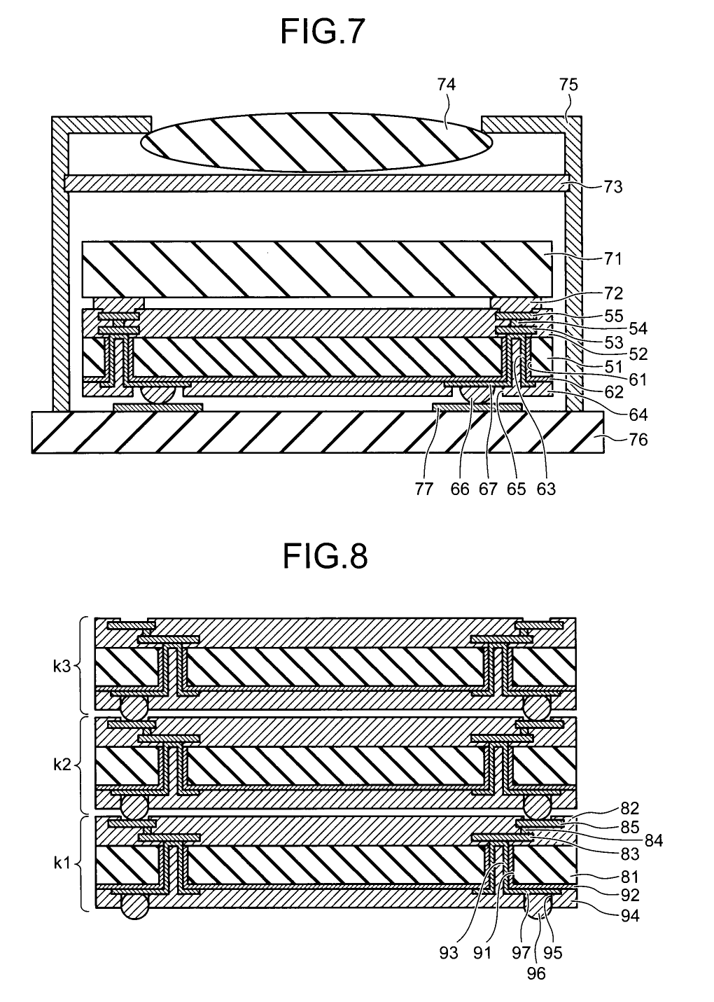

FIG. 8 is a sectional view of a schematic configuration of a semiconductor module according to a fourth embodiment of the present invention.

In FIG. 8, a semiconductor substrate 81 on which a semiconductor element such as a transistor is formed on the front side is provided in a semiconductor chip K1. A multilayer wiring layer 82 is formed on the semiconductor substrate 81. A pad electrode 83 is formed in a layer under the multilayer wiring layer 82. A pad electrode 85 is formed in a top layer of the multilayer wiring layer 82. The pad electrodes 83 and 85 are connected to each other via a contact plug 84. The multilayer wiring layer 82 can be configured the same as the wiring layer formed on the semiconductor substrate 11 shown in FIG. 1A. In particular, the pad electrode 83 can be configured the same as the pad electrode 21b shown in FIG. 1A.

A through hole 91 piercing through the semiconductor substrate 81 from the rear surface is formed in the semiconductor substrate 81. An insulating layer 92 is formed on the rear surface of the semiconductor substrate 81 and the sidewall of the through hole 91. The pad electrode 83 is electrically connected to the through hole 91. A through electrode 93 drawn out to the rear side of the semiconductor substrate 81 is embedded in the through hole 91 via an insulating layer 92. A pad electrode 97 connected to the through electrode 93 is formed on the rear surface of the semiconductor substrate 81 via the insulating layer 92. The pad electrode 97 can be arranged right below the pad electrode 85.

A solder resist film 94 that covers the through electrode 93 and the pad electrode 97 is formed on the insulating layer 92 to be embedded in the through hole 91. An opening 95 for exposing the surface of the pad electrode 97 is formed in the solder resist film 94. A protruding electrode 96 is formed on the pad electrode 97. The structure of the through electrode 93 formed on the semiconductor substrate 81 can be the same as the structure of the through electrode 45 shown in FIG. 1A.

Semiconductor chips K2 and K3 can be configured the same as the semiconductor chip K1. The semiconductor chips K1 to K3 are stacked one on top of another via protruding electrodes 96.

Because the through electrode 93 is formed on the semiconductor substrate 81, the semiconductor chips K1 to K3 can be flip-chip mounted without the number of stacks of the semiconductor chips K1 to K3 being limited. Therefore, it is possible to reduce a packaging area. In an example explained in the embodiment shown in FIG. 8, the number of stacks of the semiconductor chips K1 to K3 is three. However, the number of stacks of the semiconductor chips K1 to K3 is not limited to three and can be any number equal to or larger than two.

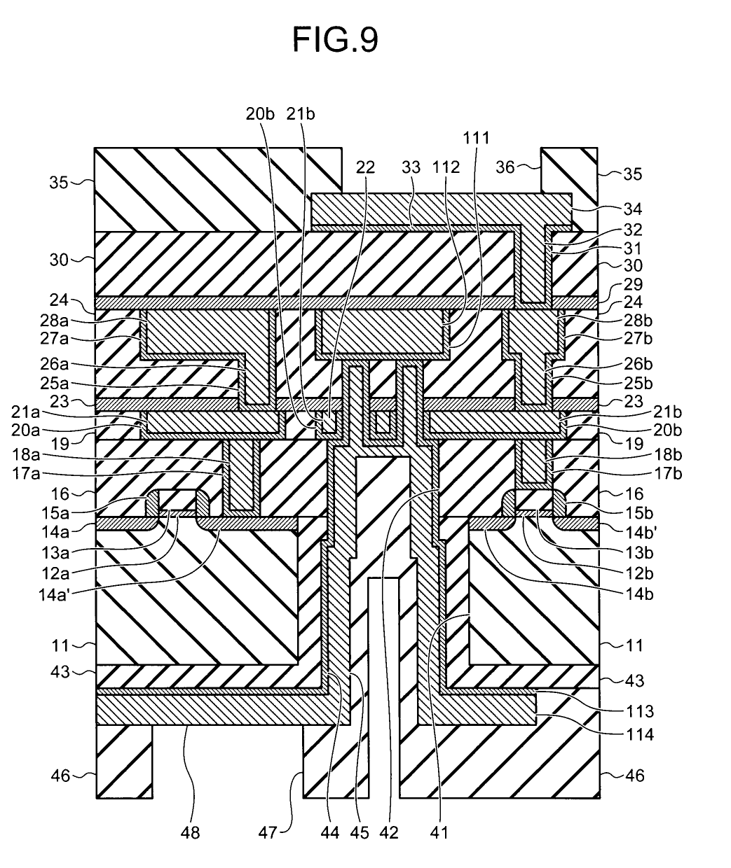

FIG. 9 is a sectional view of a schematic configuration of a semiconductor device according to a fifth embodiment of the present invention.

In FIG. 9, in addition to the configuration shown in FIG. 1A, a barrier metal film 111 and a stopper electrode 112 are provided on the semiconductor substrate 11. A barrier metal film 113 and a through electrode 114 are provided instead of the barrier metal film 44 and the through electrode 45 shown in FIG. 1A.

The stopper electrode 112 can be provided in a wiring layer in a layer above the pad electrode 21b to overlap the pad electrode 21b. For example, the stopper electrode 112 can be formed in a wiring layer same as the wrings 28a and 28b. The stopper electrode 112 is embedded in the interlayer insulating film 24 via the barrier metal film 111. A shape of the stopper electrode 112 can be an isolated pattern connected to none of the wirings formed on the semiconductor substrate 111.

The pad electrode 21b is electrically connected to the through hole 41 and the opening 42. The through electrode 114 drawn out to the rear side of the semiconductor substrate 11 is embedded in the through hole 41 and the opening 42 via the barrier metal film 113. A distal end of the through electrode 114 penetrates the etch stopper film 23 and the interlayer insulating film 24 via the openings 22 of the pad electrode 21b and is stopped by the stopper electrode 112.

Consequently, during etching for forming the opening 42 in the interlayer insulating film 16, even when the distal end of the through electrode 114 penetrates the etch stopper film 23 and the interlayer insulating film 24 via the openings 22, the through electrode 114 can be stopped by the stopper electrode 112. Therefore, it is possible to prevent a short-circuit failure of the through electrode 114.

When the distal end of the through electrode 114 is formed to penetrate a part of the pad electrode 21b via the openings 22 with the barrier metal film 20b left, for example, even when the reactive ion etching (RIE) method or the wet method is used, the openings 22 are not formed in direct contact with the electrode material of the pad electrode 21b. Therefore, corrosion and the like of the electrode material can be prevented.

For example, when the distal end of the through electrode 45 is formed to penetrate the openings 22 by using the RIE method, for example, the semiconductor substrate 11 is formed of Si and the interlayer insulating films 16 and 19 are formed of SiO₂. Then, a processing selection ratio between the semiconductor substrate 11 and the interlayer insulating films 16 and 19 is about 100 when the semiconductor substrate 11 is processed by using a SF₆ gas. Therefore, even if the semiconductor substrate 11 having the thickness of 70 micrometers is processed, the processing is stopped at a boundary between the semiconductor substrate 11 and the interlayer insulating film 16. A processing selection ratio between the interlayer insulating film 19 and the barrier metal film 20b is equal to or larger than 30 when the interlayer insulating film 16 and the interlayer insulating film 19 including the openings 22 are processed by using, for example, a C₄F₈ gas. Therefore, the openings 22 can be processed by using the barrier metal film 20b as a mask.

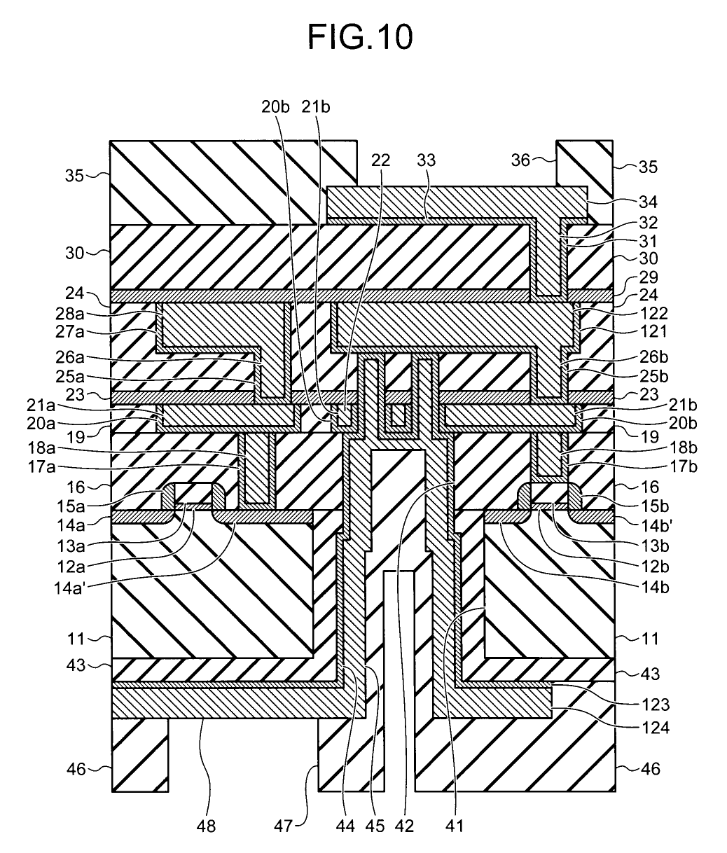

FIG. 10 is a sectional view of a schematic configuration of a semiconductor device according to a sixth embodiment of the present invention.

In FIG. 10, a barrier metal film 121 and a stopper electrode 122 are provided instead of the barrier metal film 27b and the through electrode 28b shown in FIG. 1A. A barrier metal film 123 and a through electrode 124 are provided instead of the barrier metal film 44 and the through electrode 45 shown in FIG. 1A.

The stopper electrode 122 can be provided in a wiring layer in a layer above the pad electrode 21b to overlap the pad electrode 21b and connected to wiring having the same potential as the through electrode 28b. For example, the stopper electrode 122 can be formed in a wiring layer same as the wirings 28a and 28b and embedded in the interlayer insulating film 24 via the barrier metal film 121. The stopper electrode 122 can be connected to the pad electrode 21b via the contact plug 26b and connected to the pad electrode 34 via the contact plug 32.

The pad electrode 21b is electrically connected to the through hole 41 and the opening 42. The through electrode 124 drawn out to the rear side of the semiconductor substrate 11 is embedded in the through hole 41 and the opening 42 via the barrier metal film 123. A distal end of the through electrode 124 penetrates the etch stopper film 23 and the interlayer insulating film 24 via the openings 22 of the pad electrode 21b and is stopped by the stopper electrode 122.

Consequently, during etching for forming the opening 42 in the interlayer insulating film 16, even when the distal end of the through electrode 124 penetrates the etch stopper film 23 and the interlayer insulating film 24 via the openings 22, it is possible to stop the through electrode 124 with the stopper electrode 122 without forming an isolated pattern in the layer above the pad electrode 21b. Therefore, it is possible to prevent a short-circuit failure of the through electrode 124.

When the distal end of the through electrode 124 is formed to penetrate a part of the pad electrode 21b via the openings 22 with the barrier metal film 20b left, for example, even when the reactive ion etching (RIE) method or the wet method is used, the openings 22 are not formed in direct contact with the electrode material of the pad electrode 21b. Therefore, corrosion and the like of the electrode material can be prevented.

For example, when the distal end of the through electrode 45 is formed to penetrate the openings 22 by using the RIE method, for example, the semiconductor substrate 11 is formed of Si and the interlayer insulating films 16 and 19 are formed of SiO₂. Then, a processing selection ratio between the semiconductor substrate 11 and the interlayer insulating films 16 and 19 is about 100 when the semiconductor substrate 11 is processed by using a SF₆ gas. Therefore, even if the semiconductor substrate 11 having the thickness of 70 micrometers is processed, the processing is stopped at a boundary between the semiconductor substrate 11 and the interlayer insulating film 16. A processing selection ratio between the interlayer insulating film 19 and the barrier metal film 20b is equal to or larger than 30 when the interlayer insulating film 16 and the interlayer insulating film 19 including the openings 22 are processed by using, for example, a C₄F₈ gas. Therefore, the openings 22 can be processed by using the barrier metal film 20b as a mask.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a semiconductor substrate on which a semiconductor element is formed on a front side;
a wiring layer formed on the semiconductor substrate;
a first pad electrode formed in the wiring layer;
an etch stopper film of an insulator that is formed on the first pad electrode and insulates the wiring layer; and
a through electrode that pierces through the semiconductor substrate from a rear surface of the semiconductor substrate, penetrates a part of the first pad electrode, and is stopped by the etch stopper film.

2. The semiconductor device according to claim 1, wherein the etch stopper film contains SiN, SiCN, or SiC as a main component.

3. The semiconductor device according to claim 1, further comprising a barrier metal film formed to surround the first pad electrode in cooperation with the etch stopper film.

4. The semiconductor device according to claim 1, further comprising:
a second pad electrode formed in a layer above the first pad electrode; and
a third pad electrode connected to the through electrode and formed on a rear side of the semiconductor substrate.

5. The semiconductor device according to claim 4, further comprising a protruding electrode connected to the third pad electrode, wherein
the semiconductor substrate is stacked via the protruding electrode.

6. The semiconductor device according to claim 4, further comprising:
a protruding electrode connected to the third pad electrode;
a mother board connected to the third pad electrode via the protruding electrode;
a glass substrate bonded to the front side of the semiconductor substrate;
a lens arranged on the glass substrate; and
a lens barrel that supports the lens on the glass substrate.

7. A semiconductor device comprising:
a semiconductor substrate on which a semiconductor element is formed on a front side;
a wiring layer formed on the semiconductor substrate;
a first pad electrode formed in the wiring layer;
a stopper electrode formed in a layer above the first pad electrode to overlap the first pad electrode; and
a through electrode that pierces through the semiconductor substrate from a rear surface of the semiconductor substrate, penetrates a part of the first pad electrode, and is stopped by the stopper electrode.

8. The semiconductor device according to claim 7, further comprising a first etch stopper film of an insulator that is formed on the stopper electrode and insulates the wiring layer.

9. The semiconductor device according to claim 8, wherein the first etch stopper film contains SiN, SiCN, or SiC as a main component.

10. The semiconductor device according to claim 8, further comprising a first barrier metal film formed to surround the stopper electrode in cooperation with the first etch stopper film.

11. The semiconductor device according to claim 7, further comprising:
a second pad electrode formed in a layer above the stopper electrode; and
a third pad electrode connected to the through electrode and formed on a rear side of the semiconductor substrate.

12. The semiconductor device according to claim 11, further comprising a protruding electrode connected to the third pad electrode, wherein
the semiconductor substrate is stacked via the protruding electrode.

13. The semiconductor device according to claim 11, further comprising:
a protruding electrode connected to the third pad electrode;
a mother board connected to the third pad electrode via the protruding electrode;
a glass substrate bonded to the front side of the semiconductor substrate;
a lens arranged on the glass substrate; and
a lens barrel that supports the lens on the glass substrate.

14. The semiconductor device according to claim 8, further comprising a second etch stopper film of an insulator that is formed on the first pad electrode and insulates the wiring layer.

15. The semiconductor device according to claim 14, wherein the second etch stopper film contains SiN, SiCN, or SiC as a main component.

16. The semiconductor device according to claim 14, further comprising a second barrier metal film formed to surround the first pad electrode in cooperation with the second etch stopper film.

17. The semiconductor device according to claim 7, wherein the stopper electrode is an isolated pattern that is electrically isolated before being connected to the through electrode.

18. The semiconductor device according to claim 7, wherein the stopper electrode is formed by using a part of wiring having a same potential as the through electrode.

19. A method of manufacturing a semiconductor device, comprising:
forming, on a semiconductor substrate, a wiring layer in which a pad electrode having a first opening is provided;
forming, on the pad electrode, an etch stopper film of an insulator that insulates the wiring layer;
forming a through hole that pierces through the semiconductor substrate from a rear surface of the semiconductor substrate;
forming, in the insulator, a second opening that reaches the etch stopper film via the first opening and the through hole; and
forming a through electrode embedded in the first and second openings and the through hole, electrically connected to the pad electrode, and drawn out to a rear side of the semiconductor substrate.

20. The method of manufacturing a semiconductor device according to claim 19, further comprising forming, in a layer above the pad electrode, a stopper electrode arranged to overlap the pad electrode.
